(19) United States
(12) Patent Application Publication
(10) Pub. No.: US 2025/0336693 A1
(43) Pub. Date: Oct. 30, 2025

(54) SUBSTRATE PROCESSING APPARATUS

(71) Applicant: Samsung Electronics Co., Ltd., Suwon-si (KR)

(72) Inventors: DAE-WOONG CHOI, Suwon-si (KR); OHCHEL KWON, Suwon-si (KR); HYUN-CHUL KIM, Suwon-si (KR); Jinhong Park, Suwon-si (KR); Junyoung Park, Suwon-si (KR)

(21) Appl. No.: 18/925,132

(22) Filed: Oct. 24, 2024

(30) Foreign Application Priority Data
Apr. 24, 2024 (KR) 10-2024-0054720

(51) Int. Cl. H01L 21/67; B08B 3/08; F26B 3/00; H01L 21/687

(52) U.S. Cl. CPC H01L 21/67051; B08B 3/08; F26B 3/005; H01L 21/68707

(57) ABSTRACT

A substrate processing apparatus according to an embodiment includes an index module including a load port configured to receive a substrate carrier, and a process module connected to the index module, the process module including a transfer chamber, a process chamber, and a buffer chamber. The process chamber is connected to the transfer chamber and the buffer chamber is disposed between the index module and the transfer chamber. The transfer chamber includes a transfer robot configured to transfer a substrate between the buffer chamber and the process chamber. The buffer chamber includes a buffer frame including a plurality of buffer slots, a spray nozzle disposed on the buffer frame and configured to spray a status improvement gas into a buffer slot of the plurality, and at least one buffer side sensor disposed on the buffer frame and configured to detect a state of a substrate positioned in the buffer slot.

### CROSS-REFERENCE TO RELATED APPLICATION

This application claims priority to and the benefit of Korean Patent Application No. 10-2024-0054720 filed in the Korean Intellectual Property Office on Apr. 24, 2024, the entire contents of which are incorporated herein by reference.

### BACKGROUND OF THE DISCLOSURE

### (a) Field of the Disclosure

The present disclosure relates to a substrate processing apparatus that processes substrates using a fluid in a supercritical state.

### (b) Description of the Related Art

Semiconductor devices are manufactured through various processes, including a photolithography process that forms a circuit pattern on a substrate such as a silicon wafer. During the manufacturing process of the semiconductor devices, various foreign substances such as particles, organic contaminants, and metal impurities are generated. These foreign substances may cause defects in the substrate which directly affect the performance and yield of the semiconductor device. Therefore, in the manufacturing process of the semiconductor devices, a cleaning process is performed to remove these foreign substances.

The cleaning process may be performed through a chemical process to remove the foreign substances on the substrate with chemicals, a rinse process to clean the chemicals with a rinse agent such as pure water, and a drying process to dry the substrate.

### SUMMARY OF THE DISCLOSURE

Embodiments of the inventive concept provide a substrate processing apparatus that can process a substrate while the temperature or humidity of the substrate is controlled.

However, embodiments of the inventive concept may provide other benefits that are not limited to the above-mentioned tasks and can be expanded in various ways within the range of technical ideas included in the present disclosure.

A substrate processing apparatus according to an embodiment includes an index module including a load port configured to receive a substrate carrier; and a process module connected to the index module. The process module includes a transfer chamber, a process chamber, and a buffer chamber. The process chamber is connected to the transfer chamber and the buffer chamber is disposed between the index module and the transfer chamber. The transfer chamber includes a transfer robot configured to transfer a substrate between the buffer chamber and the process chamber. The buffer chamber includes a buffer frame including a plurality of buffer slots each buffer slot configured to store a respective substrate; a spray nozzle disposed on the buffer frame and configured to spray a status improvement gas into a the buffer slot of the plurality, and at least one buffer side sensor disposed on the buffer frame and configured to detect the state of a substrate positioned in the buffer slot.

A substrate processing apparatus according to another embodiment includes an index module including a load port configured to receive a substrate carrier; a process module connected to the index module; and a controller. The process module includes a transfer chamber, a liquid treatment chamber, a drying chamber, and a buffer chamber. The liquid treatment chamber and the drying chamber are connected to the transfer chamber and the buffer chamber is disposed between the index module and the transfer chamber. The transfer chamber includes a transfer robot configured to transfers a substrate between the buffer chamber and the liquid treatment chamber and between the buffer chamber and the drying chamber. The liquid treatment chamber is configured to treat the substrate using a chemical. The drying chamber is configured to dry the substrate using a fluid in a supercritical state. The buffer chamber includes a buffer frame including a plurality of buffer, each buffer slot of the plurality configured to store a respective a substrate, a spray nozzle disposed on the buffer frame and configured to spray a status improvement gas in a buffer slot of the plurality, and at least one buffer side sensor disposed on the buffer frame and configured to detect the state of the substrate positioned in the buffer slot. The controller is configured to cause the spray nozzle to spray the status improvement gas in response to a temperature of the respective substrate or a humidity of the respective substrate detected through the buffer side sensor passes a predetermined value.

A substrate processing apparatus according to another embodiment includes an index module including a load port configured to receive a substrate carrier; a transfer chamber including a transfer robot configured to transfer a substrate to and from the load port; a liquid treatment chamber to the transfer chamber and configured to treat the substrate by using chemicals; a drying chamber connected to the transfer chamber and configured the substrate using a fluid in a supercritical state; a buffer chamber disposed between the index module and the transfer chamber; and a controller, wherein the buffer chamber includes a buffer frame including a plurality of buffer slots, each of the buffer slots configured to secure a respective substrate; a spray nozzle disposed on the buffer frame and configured to spray a status improvement gas in a buffer slot of the plurality of buffer slots; and a buffer side sensor disposed on in the buffer frame and configured to detect the state of a substrate positioned in the buffer slot, the transfer robot includes a carry-in arm configured to transfer the substrate from the buffer chamber to the liquid treatment chamber, the transfer chamber further includes at least one robot side sensor that is disposed in the transfer robot and is configured to detect a state of a substrate loaded in the carry-in arm, and the liquid treatment chamber includes a liquid treatment housing; a support plate disposed inside the liquid treatment housing and configured to support a substrate in the liquid treatment housing; a fluid supply configured to supply a fluid for processing the substrate in the liquid treatment housing; and at least one chamber side sensor that detects a state of the substrate positioned inside the liquid treatment housing.

According to embodiments, a substrate processing apparatus that manages the temperature and/or humidity of the substrate for improved processing of the substrate may be provided.

### BRIEF DESCRIPTION OF THE DRAWINGS

FIG. 1 is a top plan view of a substrate processing apparatus according to an embodiment.

FIG. 2 is a view of the inside of a buffer chamber of FIG. 1 along a first direction.

FIG. 3 is an enlarged view of a partial region of a buffer frame of the buffer chamber of in FIG. 2.

FIG. 4 is a top plan view of a buffer slot.

FIG. 5 is a view showing the arms of a transfer robot disposed in a transfer chamber of FIG. 1.

FIG. 6 is a view showing a carry-in arm of a transfer robot.

FIG. 7 is a cross-sectional view of a liquid treatment chamber of FIG. 1.

FIG. 8 is a view showing a drying chamber of FIG. 1.

FIG. 9 is a block diagram showing a control relationship of a substrate processing apparatus.

FIG. 10 is a view showing a state in which a status improvement gas is injected into the buffer slot.

FIG. 11 is a view showing a status improvement gas being sprayed when a substrate is loaded into a buffer slot.

FIG. 12 is a view showing a status improvement gas being sprayed when a substrate is unloaded from a buffer slot.

FIG. 13 is an enlarged view of a partial region of a buffer frame viewed along a first direction for a buffer frame included in a buffer chamber according to another embodiment.

FIG. 14 is a top plan view of a buffer slot in the buffer frame of FIG. 13.

FIG. 15 is a cross-sectional view of a liquid treatment chamber according to another embodiment.

FIG. 16 is a cross-sectional view of a liquid treatment chamber according to another embodiment.

### DETAILED DESCRIPTION OF THE EMBODIMENTS

The present disclosure will be described more fully hereinafter with reference to the accompanying drawings, in which various embodiments are shown. As those skilled in the art would realize, the inventive concept may be embodied in many different forms and the described embodiments may be modified in various different ways. Thus, the inventive concept should not be construed as limited to the example embodiments set forth herein.

The drawings and description are to be regarded as illustrative in nature and not restrictive. Like reference numerals designate like elements throughout the specification. Items described in the singular herein may be provided in plural, as can be seen, for example, in the drawings. Thus, the description of a single item that is provided in plural should be understood to be applicable to the remaining plurality of items unless context indicates otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Further, in the drawings, the size and thickness of each element are randomly represented for better understanding and ease of description, and the present disclosure is not limited thereto. In the drawings, the thickness of layers, films, panels, regions, etc., are exaggerated for clarity. In the drawings, for better understanding and ease of description, the thickness of some layers and areas is exaggerated.

It will be understood that when an element such as a layer, film, region, or substrate is referred to as being “connected”, “coupled”, or “on” another element, it can be directly “connected”, “coupled”, or on the other element or intervening elements may also be present. In contrast, when an element is referred to as being “directly connected”, “directly coupled”, or “directly on” another element, there are no intervening elements present (e.g., the elements may contact one another). Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements. When a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Further, throughout the specification, the phrase “on a plane” means viewing a target portion from the top, and the phrase “on a cross-section” means viewing a cross-section formed by vertically cutting a target portion from the side.

The term “substrate” may denote a base substrate (e.g., an initial semiconductor substrate forming the base of the wafer in the final wafer product, such as a bulk semiconductor substrate (e.g., formed of crystalline silicon), a silicon on insulator (SOI) substrate, etc.), or a stack structure including a base substrate and layers formed on the substrate.

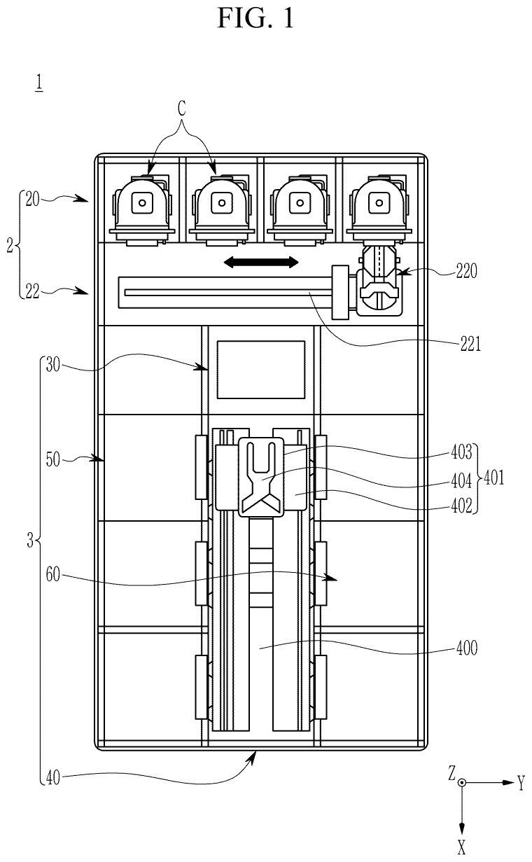

FIG. 1 is a top plan view of substrate processing apparatus 1 according to an embodiment.

Referring to FIG. 1, a substrate processing apparatus 1 according to an embodiment may include an index module 2 and a process module 3.

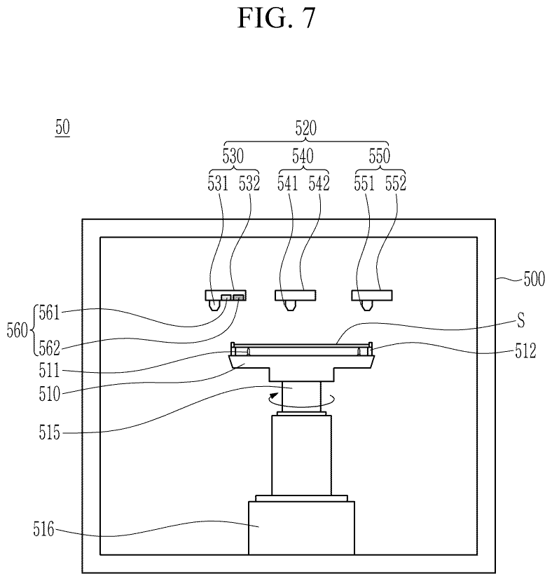

The index module 2 facilitates the loading and/or unloading of a substrate (S in FIG. 7) in and/or from the process module 3 (e.g., moved between the process module and an external location). The index module 2 may be an equipment front end module (EFEM). The index module 2 may include a load port 20 and an index chamber 22.

The load port 20, the index chamber 22, and the process module 3 may be sequentially arranged in a line. The direction in which the load port 20, the index chamber 22, and the process module 3 are arranged is referred to as a first direction X. When viewed from above, a direction orthogonal to the first direction X is referred to as a second direction Y (e.g., the first direction X and the second direction Y may define a horizontal plane), and a direction orthogonal to the first direction X and the second direction Y (e.g., a vertical direction) is referred to as a third direction Z. Additionally, the third direction Z may also be referred to as a height direction.

The index module 2 may be provided with at least one load port 20. For example, the embodiment of FIG. 1 includes 4 load ports 20. The load port 20 is disposed on a first side of the index chamber 22. In embodiments with a plurality of load ports 20, the plurality of load ports 20 may be arranged in a line along the second direction Y. The number and arrangement of the load ports 20 are not limited to the above-mentioned example, and may change depending on the footprint of substrate processing apparatus 1, a process efficiency of the substrate processing apparatus 1, an arrangement with other devices, etc. A substrate carrier C, which accommodates at least one substrate (e.g., the substrate carrier C may temporarily store at least one substrate), may be positioned in the load port 20. The substrate carrier C may be transported from a location external to the substrate processing apparatus 1 and loaded into the load port 20. Additionally, the substrate carrier C may be unloaded from the load port 20 to be returned to an external location. The substrate carrier C may be loaded with at least one substrate prior to being loaded in the load port 20. For example, the substrate carrier C may be loaded at an external location with at least one substrate and the substrate carrier C may be transported from the external location by a transfer machine such as an overhead hoist transfer (OHT). Additionally, the transporting of the substrate carrier C may be performed by an automatic guided vehicle, a rail guided vehicle, etc., or may be performed manually by a worker. The substrate carrier C accommodates at least one substrate and may be a front opening unified pod (FOUP), etc.

The index chamber 22 is disposed between the load port 20 and the process module 3. The substrate may be transferred in the transfer chamber between the load port 20 and the process module 3. The index chamber 22 may include an index robot 220 and an index rail 221. The index rail 221 may extend in a direction traverse to the first direction X, such as the second direction Y.

The index robot 220 may pick up a substrate and transport the substrate within the index chamber 22. The index rail 221 provides the path along which the index robot 220 moves. The index rail 221 may support the index robot 220. The index rail 221 may face the second direction Y so that the length direction thereof corresponds to the arrangement direction of the plurality of load ports 20. The index robot 220 may be installed on the index rail 221 and may move along the index rail 221 (e.g., the index robot may move parallel to the second direction Y). Accordingly, the index robot 220 may move along the second direction Y on the index rail 221 to a location adjacent to a particular load port 20, draw out or remove a substrate from the substrate carrier C positioned at the particular load port 20, move to a location adjacent to the process module 3, and load the substrate into the process module 3, or the index robot 220 may move along the second direction Y on the index rail 221 to a location adjacent to the process module, draw out or remove a substrate from the process module 3, move to a location adjacent to a particular load port 20, and store the substrate in substrate carrier C positioned at the particular load port 20.

In some embodiments, the index rail 221 may be omitted. For example, the index robot 220 may travel independent of an index rail, or the index robot 220 may reach each of the load ports 20 without traveling and/or may be disposed in the central portion of the index chamber 22.

The process module 3 performs a manufacturing process on a substrate loaded in the process module 3, which may be referred to as an imported substrate. In the following description, the term imported may refer to a substrate being loaded into a component and the term import may refer to loading a substrate in a component. a substrate is loaded into a component. Additionally, the term exported may refer to a substrate being removed from a component and the term export may refer to unloading a substrate from a component. The manufacturing process performed by the process module 3 may be a cleaning process. The process module 3 may include a buffer chamber 30, a transfer chamber 40, and process chambers such as a liquid treatment chamber 50 and a drying chamber 60.

The buffer chamber 30 and the transfer chamber 40 may be disposed along the first direction X. The transfer chamber 40 may be arranged so that the length direction thereof extends in the first direction X. The process chambers process the substrate using manufacturing processes, such as a liquid treatment or a drying process. The process chambers are arranged to be connected to the transfer chamber 40 (e.g., an enclosed path may connect the process chambers and the transfer chamber 40). The process chamber may include the liquid treatment chamber 50 and the drying chamber 60. The liquid treatment chamber 50 may be connected to the transfer chamber 40. The drying chamber 60 may be connected to the transfer chamber 40. The liquid treatment chamber 50 and the drying chamber 60 may be disposed on opposing sides of the transfer chamber 40 in the second direction Y. As an example, the liquid treatment chamber 50 may be disposed on a first side of the transfer chamber 40 in the second direction Y, and the drying chamber 60 may be disposed on a second side opposite to the first side in the second direction (i.e., the opposite side in the direction toward which the liquid treatment chamber 50 is disposed) of the transfer chamber 40 in the second direction Y.

The liquid treatment chamber 50 may be one of a plurality of liquid treatment chambers 50. When there is a plurality of liquid treatment chambers 50, the plurality of liquid treatment chambers 50 may be arranged along the first direction X parallel to the length direction of the transfer chamber 40. Additionally, the plurality of liquid treatment chambers 50 may be arranged to be stacked in the third direction (e.g., on top of one another). Additionally, the plurality of liquid treatment chamber 50 may be arranged by a combination of the arrangement along the first direction X and the arrangement along the third direction Z direction.

The drying chamber 60 may be one of a plurality of drying chambers 60. If there is a plurality of drying chambers 60, the plurality of drying chambers 60 may be arranged along the first direction X parallel to the length direction of the transfer chamber 40. Additionally, the plurality of drying chambers 60 may be arranged to be stacked in the third direction (e.g., on top of one another). Additionally, the plurality of drying chambers 60 may be arranged by a combination of the arrangement along the first direction X and the arrangement along the third direction Z direction.

The drying chamber 60 may perform a drying process on a substrate disposed therein. A liquid treatment process performed in the liquid treatment chamber 50 and the drying process performed in the drying chamber 60 may be performed sequentially (e.g., one after the other). In addition, any one process of the liquid treatment process performed in the liquid treatment chamber 50 or the drying process performed in the drying chamber 60 may be selectively performed in some cases.

The arrangement of the buffer chamber 30, the transfer chamber 40, the liquid treatment chamber 50, and the drying chamber 60 is not limited to the above-described examples and may be modified in other embodiments. For example, the arrangement may be modified to complement a process efficiency. In some embodiments, the liquid treatment chamber 50 and the drying chamber 60 may be disposed on the same side of the transfer chamber 40 along the first direction or arranged to be stacked on each other

The buffer chamber 30 is disposed between the index module 2 and the transfer chamber 40. The buffer chamber 30 is disposed between the index chamber 22 and the transfer chamber 40. The buffer chamber 30 temporarily stores a substrate as the substrate is being transferred between the index module 2 and the process module 3. Accordingly, buffer chamber 30 may reduce a backlog phenomenon that may occur during the process of returning the substrate to the index module and may improve the process of returning the substrate.

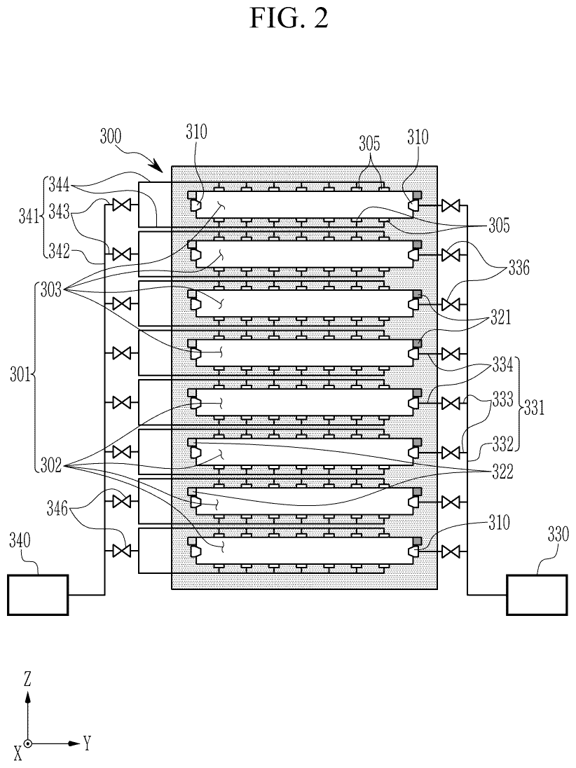

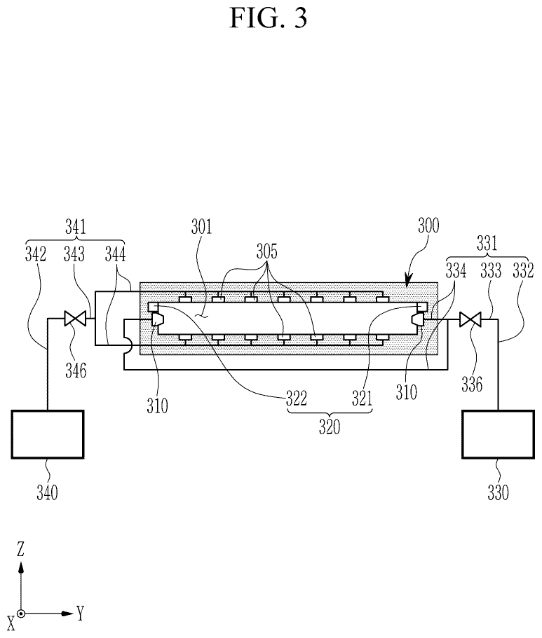

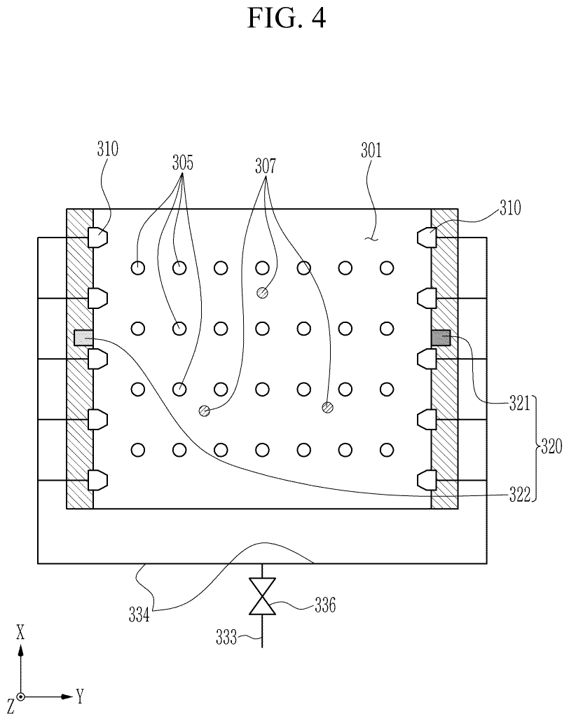

FIG. 2 is a view of the inside of the buffer chamber in FIG. 1 along the first direction. FIG. 3 is an enlarged view of a partial region of a buffer frame in FIG. 2. FIG. 4 is a top plan view of one buffer slot.

Referring to FIG. 2 to FIG. 4, the buffer chamber 30 may include a buffer frame 300, a spray nozzle 310, and a buffer side sensor 320.

The buffer frame 300 has a width in the second direction Y and a height in the third direction Z. The buffer frame 300 includes a buffer slot 301 in which a substrate may be housed. The buffer slot extends in a direction (i.e., the first direction X) from the index chamber 22 to the transfer chamber 40 which direction may be orthogonal to faces of the index chamber 22 and the transfer chamber 40 that face each other. The width of the buffer slot 301 according to the second direction Y is greater than the diameter of a substrate to be stored in the buffer slot 301. The height of the buffer slot 301 according to the third direction Z is greater than the thickness of the substrate to be stored in the buffer slot 301. The buffer slot 301 may have a length along the first direction X that may be larger than the diameter of the substrate to be housed in the buffer slot 301.

The buffer slot 301 may be one of a plurality of buffer slots 301, and the buffer slots 301 may be arranged to be spaced apart from one another in the height direction.

A substrate, which may be imported into the process module 3 from the index chamber 22, may be positioned in the buffer slot 301 (e.g., temporarily stored). Additionally, a substrate, which is exported from the process module 3 to the index chamber 22, may be housed in the buffer slot 301. A support protrusion 307 may be positioned on the bottom of the buffer slot 301 to support a substrate stored in the buffer slot 301. The support protrusion 307 may protrude upward from the bottom of an adjacent buffer slot 301.

The buffer slot 301 may be an import slot 302, an export slot 303, or a combination of both. The import slot 302 may be positioned at the bottom of the buffer frame 300. For example, among a plurality of buffer slots 301, a buffer slot positioned at the bottom (e.g., the lowermost buffer slot) may be an import slot 302. A substrate, which may be imported into the process module 3 from the index chamber 22, may be positioned in the import slot 302. The index robot 220 of the index chamber 22 exports the substrate S from the substrate carrier C located at the load port 20 to the import slot 302. Also, a transfer robot 401 of the transfer chamber 40, which will be described later, draws out the substrate S from the import slot 302. The import slot 302 may be one of a plurality of import slots 302.

The export slot 303 may be positioned at the top of the buffer frame 300. For example, among a plurality of buffer slots 301, the buffer slot 301 positioned at the top (e.g., the uppermost buffer slot 301) may be an export slot 303. Accordingly, the export slot 303 may be positioned above the import slot 302. A substrate, which is exported from the process module 3 to the index chamber 22, may be loaded in the export slot 303. The transfer robot 401 of the transfer chamber 40 may load the substrate to be exported from the process module 3 into the export slot 303. Additionally, the index robot 220 of the index chamber 22 may draw out the substrate from the export slot 303 to be imported into the substrate carrier C positioned at the load port 20. The export slot 303 may be one of a plurality of export slots 303.

In FIG. 2, there are 4 import slots 302 and 4 export slots 303 shown. However, this is just an example, and embodiments are not limited thereto. For example, based on process conditions such as the number of the liquid treatment chambers 50, the number of the drying chambers 60, the number of the load ports 20, the time required to process the substrate in the liquid treatment chamber 50, and the time required to process the substrate in the drying chamber 60, the number of the import slots 302 and the export slots 303 may vary.

The spray nozzle 310 may be disposed on the buffer frame 300. The spray nozzle 310 sprays a status improvement gas toward and/or into the buffer slot 301. The status improvement gas may improve the status such as a temperature or moisture content a substrate loaded in the buffer slot 301. The status improvement gas may be an inert gas. As an example, the status improvement gas may be a nitrogen gas, etc. The spray nozzle 310 may be disposed on an end portion of the buffer slot 301 in the width direction. The spray nozzle 310 may be disposed on a side surface of the buffer slot 301 in the width direction. The spray nozzle 310 may be one of a plurality of spray nozzles 310 and spray nozzles 310 may be disposed on both side surfaces of the end portion of the buffer slot 301 in the width direction. Additionally, the spray nozzle 310 may be disposed on only one side of the end portion of the buffer slot 301 in the width direction. FIG. 2 to FIG. 4 show an example where the spray nozzles 310 are disposed on both side surfaces of the end portion of the buffer slot 301 in the width direction. The plurality of spraying nozzles 310 may be provided along the length direction of the buffer slot 301.

The spray nozzle 310 may be connected to a gas supply 330 through a supply flow path 331. The gas supply 330 is connected to the spray nozzle 310 and supplies the status improvement gas to the spray nozzle 310. The gas supply 330 may store the status improvement gas (e.g., may be a gas storage container storing the status improvement gas).

A nozzle valve 336 may be disposed in the supply flow path 331 connecting the gas supply 330 and the spray nozzle 310. The flow of the status improvement gas supplied to the spray nozzle 310 may be adjusted depending on the shutoff state of the nozzle valve 336. That is, when the nozzle valve 336 is opened, the status improvement gas is supplied to the spray nozzle 310 (e.g., flows to), and the status improvement gas is sprayed into the buffer slot 301. When the nozzle valve 336 is closed, the supply of the status improvement gas to the spray nozzle 310 is blocked. The nozzle valve 336 may be remotely actuated by a control signal which may be provided by a controller.

The supply flow path 331 may include a main supply 332, a branch supply 333, and a nozzle connector 334. A first end of the main supply 332 may be connected to the gas supply 330. The branch supply 333may be connected to a second end of the main supply 332. The branch supply 333 may be provided in plural and be branched from the second end of the main supply 332 in a parallel structure. The nozzle connector 334 connects the spray nozzle 310, which sprays the status improvement gas toward one buffer slot 301 and the branch supply 333. The nozzle valve 336 may be disposed in the branch supply 333. Accordingly, the spraying of the status improvement gas toward one buffer slot 301 may be adjusted according to the shutoff of the nozzle valve 336, which may be controlled by a control signal from a controller.

An outlet 305 may be positioned in the buffer frame 300. The outlet 305 may be positioned to face or extend into the buffer slot 301. The outlet 305 may be positioned on at least one of the upper and lower surfaces of the buffer slot 301. That is, the outlet 305 may be positioned in the upper surface of the buffer slot 301. Additionally, the outlet 305 may be positioned in the lower surface of the buffer slot 301. Additionally, the outlet 305 may be one of a plurality of outlets 305 and a first outlet 305 may be positioned in the upper surface of the buffer slot 301 and a second outlet 305 may be positioned in the lower surface of the buffer slot 301. FIG. 2 to FIG. 4 illustrates an example where the outlets 305 are positioned on the upper and lower surfaces of the buffer slot 301. The plurality of outlets 305 may be provided along the width direction of the buffer slot 301. Additionally, the plurality of outlets 305 may be provided along the length direction of the buffer slot 301. Additionally, the plurality of outlets 305 may be provided along the width direction and length direction of the buffer slot 301.

The outlet 305 may be connected to an exhaust 340 through an exhaust flow path 341. The exhaust 340 may be an active exhaust that generates a negative pressure, such as an exhaust fan or exhaust pump. The exhaust is connected to the outlet 305 to generate a negative pressure for exhaust gases or other material from the buffer slot 301.

An outlet valve 346 may be disposed in the exhaust flow path 341 connecting the exhaust 340 and the outlet 305. The exhaust state through the outlet 305 may be adjusted depending on the shutoff state of the outlet valve 346. For example, when the outlet valve 346 is opened, negative pressure is generated in the outlet 305, and the exhaust is performed through the outlet 305. When the outlet valve 346 is closed, the exhaust through the outlet 305 is blocked. The outlet valve may be remotely actuated such as by a control signal received from a controller.

The exhaust flow path 341 may include a main exhaust 342, a branch exhaust 343, and an outlet connection 344. One end of the main exhaust 342 may be connected to the exhaust 340. The branch exhaust 343 is connected to the other end of the main exhaust 342. The branch exhaust 343 may be provided in plural and be branched from the other end of the main exhaust 342 in a parallel structure. The outlet connection 344 connects the branch exhaust 343 and the outlet 305 to one buffer slot 301. The outlet valve 346 may be disposed in the branch exhaust 343. Accordingly, the exhaust state for one buffer slot 301 may be adjusted according to the shutoff of the outlet valve 346.

The buffer side sensor 320 may be disposed on the buffer frame 300. The buffer side sensor 320 may detect the state of a substrate S positioned in the buffer slot 301. The buffer side sensor 320 may be a humidity sensor 321 and/or a temperature sensor 322. The buffer side sensor 320 may be one of a plurality of buffer side sensors 320 (e.g., a first buffer side sensor 320 may be a humidity sensor, and a second buffer side sensor 320 may be a temperature sensor).

The humidity sensor 321 is disposed on the buffer frame 300 to face the buffer slot 301 (e.g., may face inward in the buffer slot 301). As an example, the humidity sensor 321 may be disposed on a side surface of the buffer slot 301 in the width direction. Additionally, the humidity sensor 321 may be disposed on an upper surface of the buffer slot 301. Additionally, the humidity sensor 321 may be disposed on a lower surface of the buffer slot 301. FIG. 2 to FIG. 4 shows an example where the humidity sensor 321 is disposed on the side surface of the buffer slot 301 in the width direction.

The humidity sensor 321 may detect the humidity or moisture content of a substrate located in the buffer slot. As an example, the humidity sensor 321 may be a non-contact humidity sensor and directly sense the humidity or moisture content of the substrate. In addition, the humidity sensor 321 may be a contact-type humidity sensor and detect the humidity in the buffer slot 301 where the substrate is positioned, and indirectly sense the humidity of the substrate through the humidity in the buffer slot 301.

The temperature sensor 322 is disposed on the buffer frame 300 to face the buffer slot 301. As an example, the temperature sensor 322 may be disposed on a side surface of the buffer slot 301 in the width direction. Additionally, the temperature sensor 322 may be disposed on the upper surface of the buffer slot 301. Additionally, the temperature sensor 322 may be disposed on the lower surface of the buffer slot 301. FIG. 2 to FIG. 4 shows an example where the temperature sensor 322 is disposed on the side surface of the buffer slot 301 in the width direction. The temperature sensor 322 may detect the temperature of the substrate located in the buffer slot 301. As an example, the temperature sensor 322 may be provided as a non-contact temperature sensor.

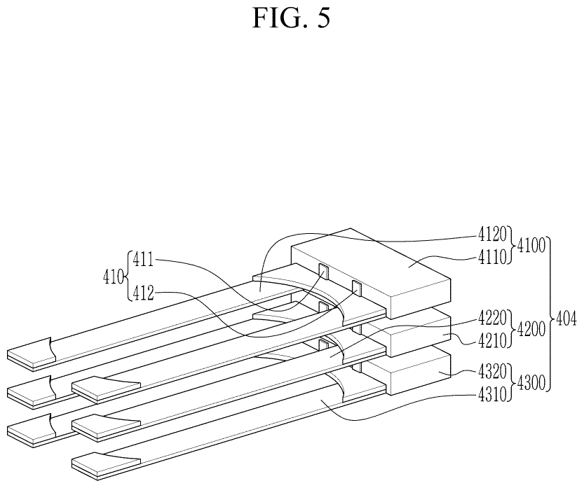

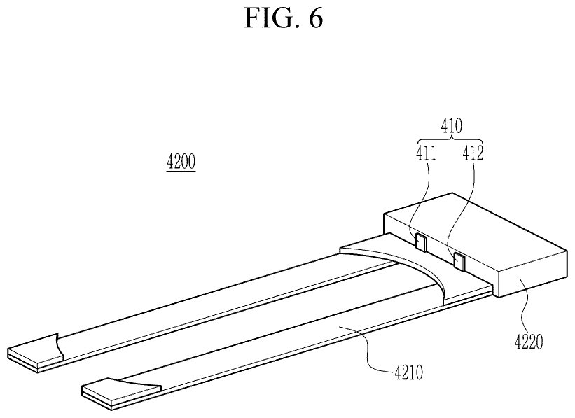

FIG. 5 is a view showing arms 404 of a transfer robot 401 disposed in the transfer chamber 40 of FIG. 1. FIG. 6 is a view showing a carry-in arm 4200 of a transfer robot 401.

Referring to FIG. 1, FIG. 5, and FIG. 6, the substrate is transferred in the

transfer chamber 40between the buffer chamber 30, the liquid treatment chamber 50, and the drying chamber 60 disposed about the circumference thereof. The buffer chamber 30 may be disposed on one side of the transfer chamber 40 in the first direction X. The liquid treatment chamber 50 and the drying chamber 60 may be disposed on one or both sides of the transfer chamber 40 in the second direction Y.

The transfer chamber 40 may include a transfer rail 400 and the transfer robot 401.

The transfer rail 400 provides a path along which the transfer robot 401 moves. The length direction of the transfer rail 400 may be in the first direction X.

The transfer robot 401 transfers a substrate. The transfer robot 401 may include a base 402, a robot body 403, and an arm 404.

The base 402 may be installed on the transfer rail 400 and move along the transfer rail 400. The robot body 403 is connected to the base 402. The robot body 403 may move along the third direction Z on the base 402 or rotate around the third direction Z. For example, an actuator such as a motor or linear actuator may cause the robot body to move along the transfer rail 400.

The arm 404 is connected to the robot body 403. The arm 404 may move relative to the robot body 403 on a plane vertical to the third direction Z.

Accordingly, the transfer robot 401 moves the base 402 on the transfer rail 400, and may transfer the substrate between the buffer chamber 30, the liquid treatment chamber 50, and the drying chamber 60 according to the operation of the robot body 403 and the arm 404.

The arm 404 may include arm frames 4110, 4210, and 4310 and hands 4120, 4220, and 4320. The arm frames 4110, 4210, and 4310 are connected to the robot body 403. The arm frames 4110, 4210, and 4310 may move relative to the robot body 403. The hands 4120, 4220, and 4320 are connected to the arm frames 4110, 4210, and 4310. Each of the arm frames 4110, 4210, and 4310 and the hands 4120, 4220, and 4320 may be connected to an adjoining element through a joint that allows at least one degree of freedom. An actuator may cause an arm frame or hand to move relative to another element and the actuator may operate in response to a control signal, such as from a controller. The substrate S may be positioned on the hands 4120, 4220, and 4320.

The arm 404 may be one of a plurality of arms 404. The plurality of arms 404 may include a carry-out arm 4100, a carry-in arm 4200, and a wet arm 4300. The carry-out arm 4100, the carry-in arm 4200, and the wet arm 4300 may be arranged along the third direction Z. The carry-out arm 4100, the carry-in arm 4200, and the wet arm 4300 can be driven individually and moved relative to the robot body 403. The carry-in arm 4200 may be disposed below the carry-out arm 4100. The wet arm 4300 may be disposed below the carry-out arm 4100 and the carry-in arm 4200.

The carry-out arm 4100 may be used to unload the substrate S from the process module 3 toward the index module 2. The carry-out arm 4100 may be used to transfer the substrate S from the drying chamber 60 to the buffer chamber 30.

The carry-in arm 4200 may be used to load the substrate S in the direction from the index module 2 to the process module 3. The carry-in arm 4200 may be used to transfer the substrate S from the buffer chamber 30 to the liquid treatment chamber 50.

The wet arm 4300 may be used to transport the substrate S inside the process module 3. The wet arm 4300 may be used to transfer the substrate S from the liquid treatment chamber 50 to the drying chamber 60.

A robot side sensor 410 may be disposed in the transfer robot 401. The robot side sensor 410 may be disposed on the arm 404. The robot side sensor 410 may detect the state of a substrate positioned on the arm 404. The robot side sensor 410 may be one of a plurality of robot side sensors 410 such as a robot side humidity sensor 411 or a robot side temperature sensor 412. For example, a plurality of robot side sensors 410 may include a first robot side sensor that is a robot side humidity sensor 411 and a second robot side sensor that is a robot side temperature sensor 412.

The robot side humidity sensor 411 may be disposed on the transfer robot 401. The robot side humidity sensor 411 may be disposed on the arm 404. The robot side humidity sensor 411 may detect the humidity of a substrate positioned on the arm 404. The robot side humidity sensor 411 may be disposed on the carry-in arm 4200 and detect the humidity of the substrate S loaded on the carry-in arm 4200. As an example, the robot side humidity sensor 411 may be provided as a non-contact humidity sensor and be disposed on the arm frame 4210 of the carry-in arm 4200. Additionally, the robot side humidity sensor 411 may be provided as a contact-type humidity sensor 321 and be disposed on the hand 4220 of the carry-in arm 4200. Additionally, the robot side humidity sensor 411 may be provided as a contact-type humidity sensor 321 and be disposed on the arm frame 4210 of the carry-in arm 4200. In this case, the robot side humidity sensor 411 may detect the humidity around the carry-in arm 4200 and indirectly sense the humidity of the substrate S through this. The robot side humidity sensor 411 may also be disposed on the carry-out arm 4100, similar to the carry-in arm 4200. Accordingly, the robot side humidity sensor 411 may detect the humidity of a substrate loaded on the carry-out arm 4100. The robot side humidity sensor 411 can also be disposed on the wet arm 4300, similar to the carry-in arm 4200. Accordingly, the robot side humidity sensor 411 may detect the humidity of a substrate loaded on the wet arm 4300.

The robot side temperature sensor 412 may be disposed in the transfer robot 401. The robot side humidity sensor 411 may be disposed on the arm 404. The robot side temperature sensor 412 may detect the temperature of the substrate positioned on the arm 404. The robot side temperature sensor 412 may be disposed on the carry-in arm 4200 and detect the temperature of the substrate loaded on the carry-in arm 4200. As an example, the robot side temperature sensor 412 may be provided as a non-contact temperature sensor and disposed on the arm frame 4210 of the carry-in arm 4200. Additionally, the robot side temperature sensor 412 may be provided as a contact-type temperature sensor and disposed on the hand 4220 of the carry-in arm 4200. The robot side temperature sensor 412 may also be disposed on the carry-out arm 4100, similar to the carry-in arm 4200. Accordingly, the robot side temperature sensor 412 may detect the temperature of the substrate loaded on the carry-out arm 4100. The robot side temperature sensor 412 may also be disposed on the wet arm 4300, similar to the carry-in arm 4200. Accordingly, the robot side temperature sensor 412 may detect the temperature of the substrate loaded on the wet arm 4300.

FIG. 6 shows an example in which the robot side humidity sensor 411 and the robot side temperature sensor 412 are arranged in a region near the hand 4220 from the arm frame 4210 of the carry-in arm 4200, but this is an example, and the robot side humidity sensor 411 and the robot side temperature sensor 412 may be disposed in other regions of the transfer robot 401.

FIG. 7 is a cross-sectional view of a liquid treatment chamber 50 in FIG. 1.

Referring to FIG. 7, the liquid treatment chamber 50 may include a liquid treatment housing 500, a support plate 510, a fluid supply 520, and a chamber side sensor 560.

The liquid treatment chamber 50 may perform a liquid treatment process that treats a substrate S using chemicals. As an example, the liquid treatment chamber 50 may perform a chemical process, a rinse process, and an organic solvent substitution process.

The liquid treatment housing 500 provides a space inside where the treatment of the substrate S is performed.

The support plate 510 is disposed inside the liquid treatment housing 500. The support plate 510 supports the substrate S. The support plate 510 may be rotated around the third direction Z. As an example, the lower part of the support plate 510 may be connected to the upper part of the support shaft 515. The lower part of the support shaft 515 may be connected to a drive 516. The support shaft 515 may be rotated by a power provided by the drive 516.

A plurality of supporting pins 511 may be disposed on the support plate 510. The support pin 511 may be provided to be protruded from the upper surface of the support plate 510 in the third direction Z. The supporting pins of the plurality of supporting pins 511 may be arranged to be spaced apart from each other at a regular or irregular interval. As an example, the supporting pins 511 may be arranged on a cyclic ring with a fixed radius. When the substrate S is positioned on the support plate 510, the bottom of the substrate S is raised on the support pin 511.

A plurality of chuck pins 512 may be disposed on the support plate 510. The chuck pin 512 may be provided to be protruded in the third direction Z from the upper surface of the support plate 510. The length of the chuck pin 512 in the third direction Z is longer than that of the support pin 511, and the top of the chuck pins 512 is positioned above the top of the support pin 511. The chuck pins 512 are disposed at a position farther away from the center of the support plate 510 than the support pin 511. The chuck pins 512 may move between the fixed position and the pickup position along the radial direction of the support plate 510. The fixed position is a position away from the center of the support plate 510 by a distance corresponding to the radius of the substrate S, and the pickup position is a position further away from the center of the support plate 510 than the fixed position. The chuck pin 512 are positioned at the pickup position when the substrate S is loaded on the support plate 510 by the transfer robot 401. When the substrate S is loaded on the support plate 510, the chuck pin 512 move to the fixed position and fix the substrate S by being contact with the side of the substrate S during the process. Accordingly, the chuck pin 512 may prevent the substrate S from being separated by a torque when the support plate 510 rotates. When the process is completed, the chuck pin 512 move to the pickup position so that the transfer robot 401 may pick up the substrate S.

The fluid supply 520 may supply a fluid for processing the substrate S over the support plate 510. Accordingly, the substrate S positioned on the support plate 510 may be coated by the fluid for processing the substrate. The fluid supply 520 may include nozzles 531, 541, and 551 and nozzle supports 532, 542, and 552.

The nozzles 531, 541, and 551 may spray the fluid for processing the substrate S. The nozzle support 532, 542, and 552 are connected to the nozzles 531, 541, and 551. The nozzle support 532, 542, and 552 may move the positions of the nozzles 531, 541, and 551. Accordingly, the nozzles 531, 541, and 551 may move between the process position and the standby position. The process position is the position where the nozzles 531, 541, and 551 face the support plate 510 in the third direction Z. The standby position is a position outside the region where the nozzles 531, 541, and 551 face the support plate 510 in the third direction Z.

The fluid supply 520 may include a chemical fluid supply 530, a rinse fluid supply 540, and a substitution fluid supply 550. The chemical fluid supply 530, the rinse fluid supply 540, and the substitution fluid supply 550 may spray different fluids.

The chemical fluid supply 530 may include a chemical nozzle 531 and a chemical nozzle support 532.

The chemical nozzle 531 may spray chemicals. The chemical may be a cleaning solution. For example, the chemical may be a hydrogen peroxide solution, a solution mixing hydrogen peroxide solution with ammonia, hydrochloric acid, or sulfuric acid, or a hydrofluoric acid solution. The chemical nozzle support 532 is connected to the chemical nozzle 531. The chemical nozzle support 532 may move the chemical nozzle 531 to the standby position and the process position.

The rinse fluid supply 540 may include a rinse nozzle 541 and a rinse nozzle support 542. The rinse nozzle 541 may a spray rinse liquid. The rinse liquid may be ultrapure water, etc. The rinse nozzle support 542 is connected to the rinse nozzle 541. The rinse nozzle support 542 may move the rinse nozzle 541 to the standby position and the process position. After the chemical is supplied to the substrate S, the rinse fluid supply 540 may supply the rinse solution to the substrate S to remove the chemical remaining on the substrate S.

The substitution fluid supply 550 may include a substitution nozzle 551 and a substitution nozzle support 552. The substitution nozzle 551 may spray an organic solvent. Examples of organic solvents include isopropyl alcohol, ethyl glycol, 1-propanol, tetra hydraulic franc, 4-hydroxy, 4-methyl, 2-pentanone, 1-butanol, 2-butanol, methanol, ethanol, n-propyl alcohol, dimethyl ether, etc.

The substitution nozzle support 552 is connected to the substitution nozzle 551. The substitution nozzle support 552 may move the substitution nozzle 551 to the standby position and the process position. After the rinse solution is supplied to the substrate S, the substitution fluid supply 550 may supply the organic solvent to the substrate S so that the rinse solution remaining on the substrate S is redisposed with the organic solvent.

The chamber side sensor 560 may detect the state of the substrate S positioned inside the liquid treatment housing 500. The chamber side sensor 560 may be disposed inside the liquid treatment housing 500.

The chamber side sensor 560 may include a chamber side humidity sensor 561 and a chamber side temperature sensor 562.

The chamber side humidity sensor 561 may be disposed on the fluid supply 520. The chamber side humidity sensor 561 may be disposed on the nozzle supports 532, 542, and 552. As an example, the chamber side humidity sensor 561 may be disposed on the chemical fluid supply 530. The chamber side humidity sensor 561 may be disposed on the chemical nozzle support 532. The chamber side humidity sensor 561 may detect the humidity of the substrate S. As an example, the chamber side humidity sensor 561 is provided as a non-contact humidity sensor and may directly sense the humidity of the substrate S positioned on the support plate 510. In addition, the chamber side humidity sensor 561 is provided as a contact-type humidity sensor 321, which detects the humidity of the space where the substrate S is positioned, and may indirectly sense the humidity of the substrate S through this.

The chamber side temperature sensor 562 may be disposed on the fluid supply 520. The chamber side temperature sensor 562 may be disposed on the nozzle supports 532, 542, and 552. As an example, the chamber side temperature sensor 562 may be disposed on the chemical fluid supply 530. The chamber side temperature sensor 562 may be disposed on the chemical nozzle support 532. The chamber side temperature sensor 562 may detect the temperature of the substrate S. As an example, the chamber side temperature sensor 562 is provided as a non-contact temperature sensor and may detect the temperature of the substrate S positioned on the support plate 510.

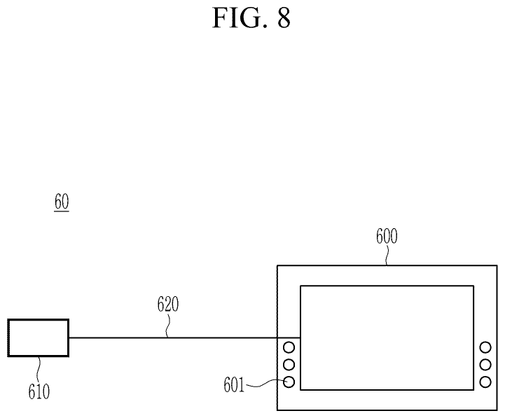

FIG. 8 is a view showing the drying chamber 60 in FIG. 1.

Referring to FIG. 8, the drying chamber 60 may dry a substrate using a supercritical fluid. The drying chamber 60 may include a drying housing 600 and a heater 601.

The drying housing 600 provides a space inside where the drying process is performed. The drying housing 600 may be provided with a pressure-resistant structure that can withstand high pressure.

The heater 601 may be disposed in the drying housing 600 and heat the interior of the drying housing 600. The heater 601 may be disposed to be embedded in the drying housing 600. As an example, the heater 601 may generate heat using a resistance heating method. As the interior of the drying housing 600 is heated, a fluid supplied into the drying housing 600 may maintain a supercritical state more effectively.

The drying housing 600 is connected to the process fluid supply 610 through the process fluid flow path 620. The process fluid supply 610 may supply the fluid in the supercritical state from the drying housing 600. The process fluid supply 610 may generate and store the fluid in the supercritical state. For example, the process fluid supply 610 may heat the process fluid to a temperature above a threshold temperature and may pressurize the process fluid to a pressure above a threshold pressure to the process fluid, which may be dioxide carbon, etc., thereby putting the process fluid in a supercritical state. The fluid in the supercritical state generated in the process fluid supply 610 may be supplied to the drying housing 600 through the process fluid flow path 620.

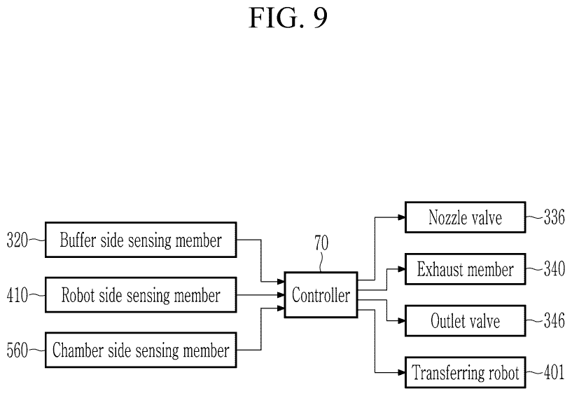

FIG. 9 is a block diagram showing a control relationship of a substrate processing apparatus 1.

Referring to FIG. 9, the controller 70 controls the components of the substrate processing apparatus 1. Although not illustrated, the controller 70 can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the processing controller (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller can include antennas, communication interfaces that provide wireless and/or wire line digital and/or analog interface to one or more components such as sensors and actuators, a power source that provides an appropriate alternating current (AC) or direct current (DC) to power one or more components of the controller, and a bus that allows communication among the various disclosed components of the controller.

Components that move such as the described robots and valves may be at least partially controlled by the controller 70. The motion may be effectuated by a motor or actuator coupled to the component and that communicates with the controller 70 through control signals. The variously described sensors may communicate with the controller 70 over a data connection.

The controller 70 may receive data about the state of the substrate S positioned in the buffer slot 301 from the buffer side sensor 320. The controller 70 may receive data about the humidity of the substrate S positioned in the buffer slot 301 from the humidity sensor 321. The controller 70 may receive data about the temperature of the substrate S positioned in the buffer slot 301 from the temperature sensor 322.

The controller 70 may receive data about the state of the substrate S positioned on the transfer robot 401 from the robot side sensor 410. The controller 70 may receive data about the humidity of the substrate S positioned on the transfer robot 401 from the robot side humidity sensor 411. The controller 70 may receive data about the temperature of the substrate S positioned on the transfer robot 401 from the robot side temperature sensor 412.

The controller 70 may receive data about the state of the substrate S positioned in the liquid treatment chamber 50 from the chamber side sensor 560. The controller 70 may receive data about the humidity of the substrate S positioned in the liquid treatment chamber 50 from the chamber side humidity sensor 561. The controller 70 may receive data about the temperature of the substrate S positioned in the liquid treatment chamber 50 from the chamber side temperature sensor 562.

The controller 70 may control the shutoff state of the nozzle valve 336 and control the injection of the status improvement gas into the buffer slot 301.

The controller 70 may open the nozzle valve 336 so as to spray the status improvement gas into the buffer slot 301. The controller 70 may close the nozzle valve 336 so as to stop the injection of the status improvement gas into the buffer slot 301. The controller 70 may control the amount of the status improvement gas injected into the buffer slot 301 by adjusting the opening degree of the nozzle valve 336. The controller 70 may individually control the plurality of nozzle valves 336 to individually control the state in which the status improvement gas is sprayed for each of the plurality of buffer slots 301.

The controller 70 may control the exhaust 340 and control the exhaust condition through the outlet 305. The controller 70 may operate the exhaust 340 to perform the exhaust of the buffer slot 301 through the outlet 305. The controller 70 may stop the exhaust 340 to stop the exhaust from the buffer slot 301 through the outlet 305.

The controller 70 may control the shutoff state of the outlet valve 346 to control the exhaust state through the outlet 305. The controller 70 may open the outlet valve 346 to perform the exhaust of the buffer slot 301 through the outlet 305. The controller 70 may close the outlet valve 346 to stop the exhaust from the buffer slot 301 through the outlet 305. Additionally, the controller 70 may control the amount of the gas exhausted through the outlet 305 by adjusting the degree of the opening of the outlet valve 346. The controller 70 may individually control the plurality of outlet valves 346 and individually control the exhaust status of each of the plurality of buffer slots 301.

The controller 70 may control the transfer robot 401 to pick up the substrate S, which is brought into the process module 3 from the index chamber 22, from the buffer chamber 30 to be returned to the liquid treatment chamber 50. The controller 70 may control the transfer robot 401 to pick up the substrate S, which is imported into the process module 3 from the index chamber 22, from the import slot 302 through the carry-in arm 4200 to be returned to the liquid treatment chamber 50.

The controller 70 may control the transfer robot 401 to pick up the substrate S, which has undergone the liquid treatment process, from the liquid treatment chamber 50 to be returned to the drying chamber 60. The controller 70 may control the transfer robot 401 to pick up substrate S, which has undergone the liquid treatment process, from the liquid treatment chamber 50 through the wet arm 4300 to be transferred to the drying chamber 60.

The controller 70 may control the transfer robot 401 to pick up substrate S, which has undergone the drying process, from the drying chamber 60 to be returned to the buffer chamber 30. The controller 70 may control the transfer robot 401 to pick up substrate S, which has undergone the drying process, from the drying chamber 60 through the carry-out arm 4100 to be returned to the buffer chamber 30.

The controller 70 may control the transfer robot 401 to pick up substrate S in which abnormal conditions are detected from the liquid treatment chamber 50 to be returned to the buffer chamber 30. The controller 70 may control the transfer robot 401 to pick up substrate S with the abnormal condition detected through the carry-in arm 4200 and return it to the import slot 302 of the buffer chamber 30.

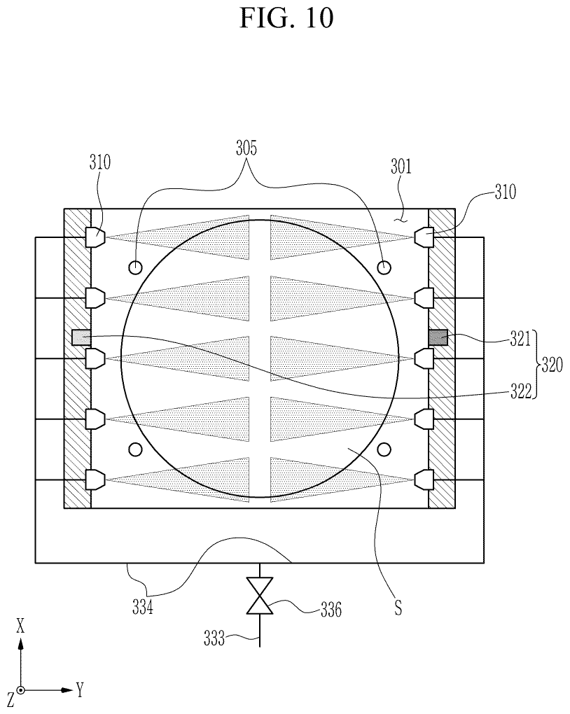

FIG. 10 is a view showing a state in which a status improvement gas is injected into a buffer slot 301.

Referring to FIG. 10, in the state that the substrate S is positioned in the buffer slot 301, the controller 70 may control the status improvement gas to be sprayed. Additionally, when the status improvement gas is injected, the controller 70 may control the exhaust 340, the outlet valve 346, or the exhaust 340 and the outlet valve 346 so that the exhaustion occurs through the outlet 305. When the status improvement gas is sprayed, the substrate S may be cooled. Additionally, when the status improvement gas is sprayed, a moisture may evaporate from the substrate S, thereby lowering the humidity of the substrate S. Additionally, when the status improvement gas is sprayed, particles attached to the substrate S may be removed.

For example, when the substrate S, which is imported from the index module 2 to the process module 3, is positioned in the import slot 302, the controller 70 may control the status improvement gas to be sprayed into the import slot 302. Additionally, the controller 70 may ensure that when the status improvement gas is injected into the import slot 302, the exhaust is performed through the outlet 305 of the import slot 302.

Additionally, when the substrate S, which is imported from the index module 2 to the process module 3, is positioned in the import slot 302, the controller 70 may monitor the state of the substrate S through the buffer side sensor 320. Additionally, the controller 70 may cause the status improvement gas to be sprayed when it detects that the temperature of the substrate S passes a predetermined value or the humidity of the substrate S passes a predetermined value. The predetermined value may be a threshold value. For example, the controller may cause the status improvement gas to be sprayed in response to the temperature of the substrate S rising above a threshold value, or in another example, the controller may cause the status improvement gas to be sprayed in response to the temperature of the substrate S falling below a threshold value.

Additionally, when a substrate S, which is being imported from the index module 2 to the process module 3, is positioned in the import slot 302, the controller 70 may cause the status improvement gas to be injected in batches. For example, when the temperature of the substrate S is detected to be below a predetermined value, the controller 70 may stop the spray of the status improvement gas. In another example, when the status improvement gas is sprayed and the humidity of the substrate S is detected to be below a predetermined value, the controller 70 may stop the spraying of the status improvement gas. In another example, when the status improvement gas is sprayed and the temperature of the substrate S is detected to be below a predetermined value and the humidity of the substrate S is detected to be below a predetermined value, the controller 70 may stop the spraying of the status improvement gas.

Additionally, when the substrate S, which is imported from the index module 2 to the process module 3, is positioned in the import slot 302, the controller 70 may cause the status improvement gas to be sprayed in batches. And, when the transfer robot 401 loads the substrate S and the import slot 302 becomes empty, the controller 70 may stop the injection of the status improvement gas.

Additionally, when the substrate S, which is exported from the process module 3 to the index module 2, is positioned in the export slot 303, the controller 70 may cause the status improvement gas to be sprayed into the export slot 303. Additionally, the controller 70 ensures that when the status improvement gas is sprayed into the export slot 303, the exhaust is performed through the outlet 305 of the export slot 303.

Additionally, when the substrate S, which is exported from the process module 3 to the index module 2, is positioned in the export slot 303, the controller 70 may monitor the state of the substrate S through the buffer side sensor 320. Additionally, the controller 70 may cause the status improvement gas to be sprayed when it detects that the temperature of the substrate S passes a predetermined value or the humidity of the substrate S is above a predetermined value.

Additionally, when the substrate S, which is exported from the process module 3 to the index module 2, is positioned in the export slot 303, the controller 70 may cause the status improvement gas to be sprayed all at once. And, when the temperature of the substrate S is detected to be below a predetermined value, the controller 70 may stop the injection of the status improvement gas. In an example, when the status improvement gas is injected and the humidity of the substrate S is detected to be below a predetermined value, the controller 70 may stop the injection of the status improvement gas. In an example, when the status improvement gas is injected and the temperature of the substrate S is detected to be below a predetermined value and the humidity of the substrate S is detected to be below a predetermined value, controller 70 may stop the spraying of the status improvement gas.

Additionally, when the substrate S, which is exported from the process module 3 to the index module 2, is positioned in the export slot 303, the controller 70 may cause the status improvement gas to be sprayed all at once. Also, when the index robot 220 exports the substrate S and the export slot 303 becomes empty, the controller 70 may stop the injection of status improvement gas.

Additionally, when the substrate S is positioned in the transfer robot 401, the controller 70 may monitor the status of the substrate S through the robot side sensor 410. And, when it is detected that the temperature of the substrate S positioned in the carry-in arm 4200 is above a predetermined value or the humidity of the substrate S is above a predetermined value, the controller 70 may return the substrate S to the buffer chamber 30. Accordingly, the substrate S is returned to the buffer chamber 30 before the liquid treatment in the liquid treatment chamber 50. Hereinafter, the substrate S, which is brought from the index module 2 to the process module 3 and returned to the buffer chamber 30 before the liquid treatment process, is referred to as a substrate to be improved. At this time, the controller 70 may position the substrate S to be improved in the import slot 302. Accordingly, the substrate S before the completion of processing in the process module 3 is positioned in the export slot 303, thereby preventing the export slot 303 from being contaminated by the substrate S. Additionally, the controller 70 may cause the status improvement gas to be sprayed into the import slot 302 where the substrate to be improved is positioned. Accordingly, the condition of the substrate to be improved may be improved by lowering the temperature and humidity by the status improvement gas. Afterwards, when the temperature of the substrate to be improved is detected to be below a predetermined value through the buffer side sensor 320, the controller 70 may bring in the substrate S through the transfer robot 401. In contrast, when the humidity of the substrate S to be improved is detected to be below a predetermined value through the buffer side sensor 320, the controller 70 may bring in the substrate S through the transfer robot 401. On the other hand, when it is detected that the temperature of the substrate S to be improved is below a predetermined value through the buffer side sensor 320 and the humidity of the substrate S to be improved is below a predetermined value, the controller 70 may import the substrate S through the transfer robot 401. At this time, the controller 70 may pick up the substrate S through the carry-in arm 4200 and then return it to the liquid treatment chamber 50.

Additionally, when the substrate S is positioned in the liquid treatment chamber 50, the controller 70 may monitor the state of the substrate S through the chamber side sensor 560. Additionally, if it is detected that the temperature of the substrate S is above a predetermined value or the humidity of the substrate S is above a predetermined value, the controller 70 may return the substrate S to be improved to the buffer chamber 30. Accordingly, the substrate S to be improved is returned to the buffer chamber 30 before the liquid treatment in the liquid treatment chamber 50. At this time, the controller 70 may pick up the substrate S to be improved through the carry-in arm 4200 to be returned to the buffer chamber 30. The controller 70 may position the substrate S to be improved into the import slot 302. Accordingly, the substrate S before the completion of processing in the process module 3 is positioned in the export slot 303, thereby preventing the export slot 303 from being contaminated by the substrate S. Additionally, the controller 70 may cause the status improvement gas to be injected into the import slot 302 where the substrate S to be improved is positioned. Accordingly, the condition of the substrate S subject to the improvement may be improved by lowering the temperature and humidity by the status improvement gas. Afterwards, when the temperature of the substrate S to be improved is detected to be below a predetermined value through the buffer side sensor 320, the controller 70 may transfer the substrate S through the transfer robot 401. In an example, when the humidity of the substrate S to be improved is detected to be below a predetermined value through the buffer side sensor 320, the controller 70 may bring in the substrate S through the transfer robot 401. On the other hand, when it is detected that the temperature of the substrate S to be improved is below a predetermined value through the buffer side sensor 320 and the humidity of the substrate S to be improved is below a predetermined value, the controller 70 may import the substrate S through the transfer robot 401. At this time, the controller 70 may pick up the substrate S through the carry-in arm 4200 and then return it to the liquid treatment chamber 50.

The substrate processing apparatus 1 according to an embodiment may manage the temperature or humidity of the substrate S. The substrate S brought into the substrate processing apparatus 1 is positioned in the buffer chamber 30 and waits for some time. Generally, the processing of the substrate S is carried out while the plurality of substrate S is brought in inside the process module 3. Accordingly, a deviation may occur in the waiting time of the substrate S in the buffer chamber 30. As the waiting time for the substrate S increases in the buffer chamber 30, the temperature or humidity of the substrate S changes. If the temperature or humidity of substrate S is outside the appropriate range, it causes poor processing and a decrease in yield. On the other hand, in the substrate processing apparatus 1 according to an embodiment, even when the waiting time for the substrate S in the buffer chamber 30 increases, the temperature and humidity or temperature and humidity of the substrate S are managed in response thereto. Accordingly, defects and yield reduction of the processed substrate S are prevented or reduced.

Additionally, the substrate processing apparatus 1 according to an embodiment additionally manages the temperature or humidity of the substrate S introduced into the section after the buffer chamber 30 in the process module 3.

In addition, the substrate processing apparatus 1 according to an embodiment removes the particles attached to the substrate S during the process of treating the substrate S with the status improvement gas, thereby preventing or reducing the occurrence of defects and reduction in yield.

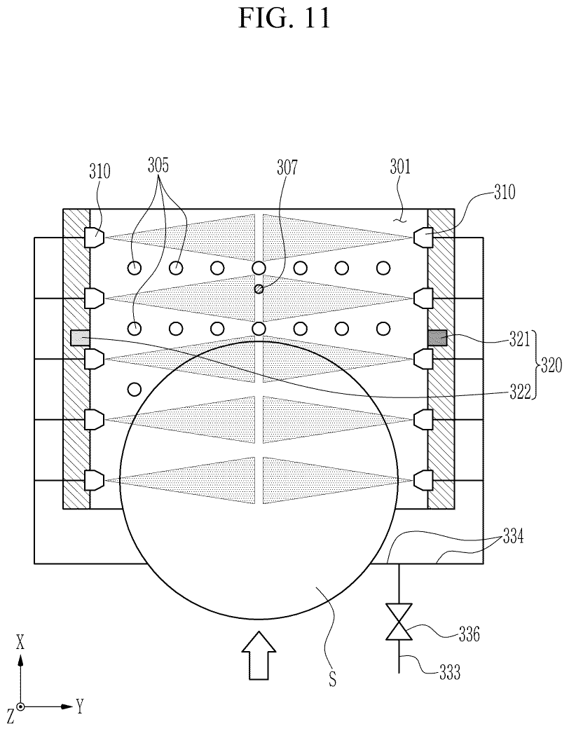

FIG. 11 is a view showing a status improvement gas being sprayed when a substrate is loaded into a buffer slot 301.

Referring to FIG. 11, in the process of positioning the substrate S in the buffer slot 301, the controller 70 may control the injection of the status improvement gas. Additionally, when the status improvement gas is injected, the controller 70 may control the exhaust 340, the outlet valve 346, or the exhaust 340, and the outlet valve 346 so that exhaustion occurs through the outlet 305.

For example, when the substrate S, which is imported from the index module 2 to the process module 3, is positioned in the import slot 302, the controller 70 may cause the status improvement gas to be sprayed into the import slot 302. Additionally, the controller 70 may ensure that when the status improvement gas is injected into the import slot 302, the exhaust is performed through the outlet 305 of the import slot 302.

Additionally, in the process of positioning the substrate S, which is exported from the process module 3 to the index module 2, into the export slot 303, the controller 70 may cause the status improvement gas to be sprayed into the export slot 303. Additionally, when status improvement gas is injected into the export slot 303, the controller 70 may ensure that the exhaust is performed through the outlet 305 of the export slot 303.

Additionally, in the process of positioning the substrate S to be improved in the import slot 302, the controller 70 may cause the status improvement gas to be sprayed into the import slot 302. Additionally, when the status improvement gas is injected into the import slot 302, the controller 70 may ensure that the gas is exhausted through the outlet 305 of the import slot 302.

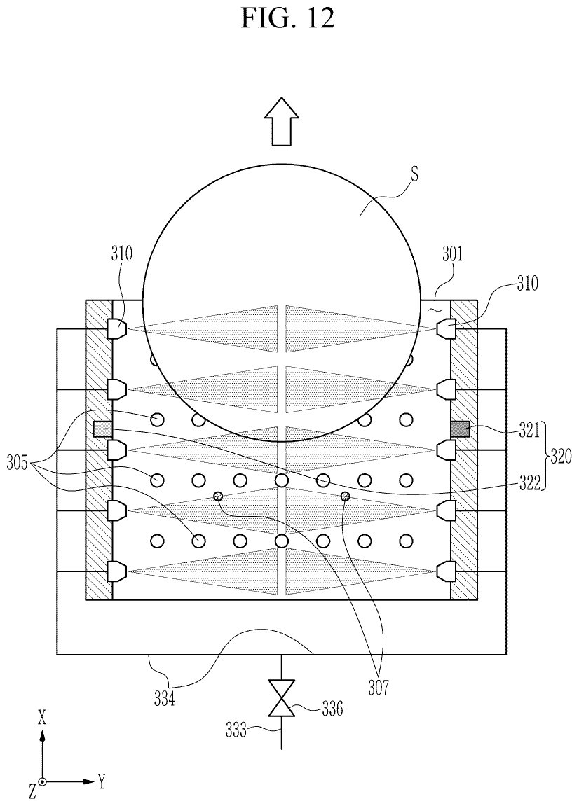

FIG. 12 is a view showing a state in which a status improvement gas is sprayed when a substrate is unloaded into a buffer slot 301.

Referring to FIG. 12, in the process of the substrate S being unloaded in the buffer slot 301, the controller 70 may control the injection of the status improvement gas. Additionally, when the status improvement gas is injected, the controller 70 may control the exhaust 340, the outlet valve 346, or the exhaust 340 and the outlet valve 346 so that exhaustion occurs through the outlet 305.

For example, in the process of unloading the substrate S, which is imported from the index module 2 to the process module 3, in the import slot 302, the controller 70 may cause the status improvement gas to be sprayed into the import slot 302. Additionally, when the status improvement gas is injected into the import slot 302, the controller 70 may ensure that the gas is exhausted through the outlet 305 of the import slot 302.

Additionally, in the process of unloading the substrate S, which is exported from the process module 3 to the index module 2, from the export slot 303, the controller 70 may cause the status improvement gas to be sprayed into the export slot 303. Additionally, when the status improvement gas is injected into the export slot 303, the controller 70 may ensure that the gas is exhausted through the outlet 305 of the corresponding export slot 303.

Additionally, in the process of unloading the substrate S to be improved from the import slot 302, the controller 70 may cause the status improvement gas to be sprayed into the import slot 302. Additionally, when the status improvement gas is injected into the import slot 302, the controller 70 may ensure that the gas is exhausted through the outlet 305 of the import slot 302.

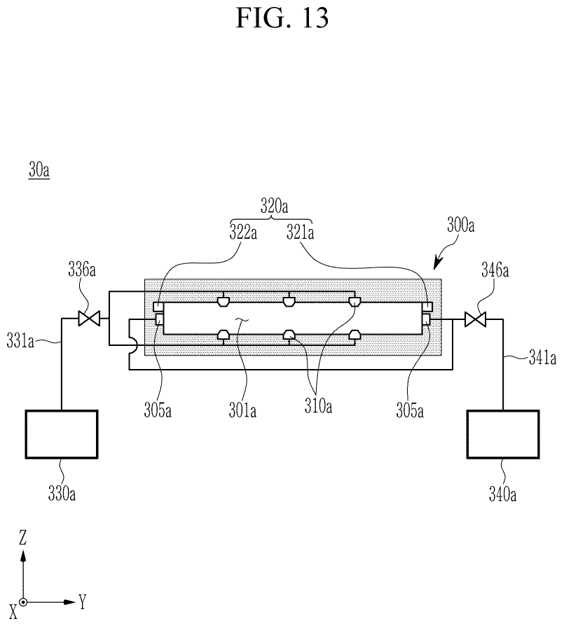

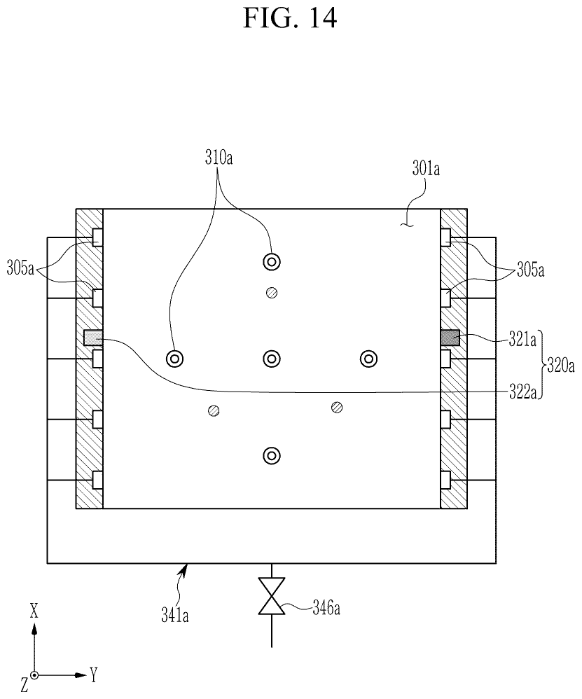

FIG. 13 is an enlarged view of a partial region of a drawing viewed along a first direction for a buffer frame 300a included in a buffer chamber 30a according to another embodiment. FIG. 14 is a top plan view of one buffer slot in a buffer frame 300a of FIG. 13.

Referring to FIG. 13 and FIG. 14, the buffer chamber 30a may include a buffer frame 300a, a spray nozzle 310a, and a buffer side sensor 320a.

The structure of the buffer frame 300a is the same or similar to the buffer frame 300 described above in FIG. 1 to FIG. 4, repeated explanations will be omitted.

The spray nozzle 310a may be disposed in the buffer frame 300a. The spray nozzle 310a sprays the status improvement gas toward and/or into the buffer slot 301a. The status improvement gas may be an inert gas. As an example, the status improvement gas may be a nitrogen gas, etc. The spray nozzle 310a may be disposed on at least one of the upper and lower surfaces of the buffer slot 301a. That is, the spray nozzle 310a may be disposed on the upper and lower surfaces of the buffer slot 301a. Additionally, the spray nozzle 310a may be disposed only on the upper surface of the buffer slot 301a. Additionally, the spray nozzle 310a may be disposed only on the lower surface of the buffer slot 301a. FIG. 13 illustrates the case where the spray nozzle 310a is disposed on the upper and lower surfaces of the buffer slot 301a. The plurality of spray nozzles 310a may be provided along the length direction of the buffer slot 301a. Additionally, the plurality of spray nozzles 310a may be provided along the width direction of the buffer slot 301a. Additionally, the plurality of spray nozzles 310a may be provided along the length direction and width direction of the buffer slot 301a.

The spray nozzle 310a may be connected to the gas supply 330a through the supply flow path 331a. The gas supply 330a is connected to the spray nozzle 310a and supplies the status improvement gas to the spray nozzle 310a. The gas supply 330a may store the status improvement gas.

A nozzle valve 336a may be disposed on the supply flow path 331a connecting the gas supply 330a and the spray nozzle 310a. The state of the status improvement gas supplied to the spray nozzle 310a may be adjusted depending on the shutoff state of the nozzle valve 336a. That is, when the nozzle valve 336a is opened, the status improvement gas is supplied to the spray nozzle 310a, and the status improvement gas is sprayed into the buffer slot 301a. When the nozzle valve 336a is closed, the supply of the status improvement gas to the spray nozzle 310a is blocked. The structure of the supply flow path 331a is the same or similar to the supply flow path 331 described above in FIG. 2 to FIG. 4 and explanations that would be repetitive may be omitted.

An outlet 305a may be positioned in the buffer frame 300a. The outlet 305a may be positioned to face the buffer slot 301a. The outlet 305a may be positioned at least on one end portion of the buffer slot 301a in the width direction. That is, the outlet 305a may be positioned at both end portions of the buffer slot 301a in the width direction. Additionally, the outlet 305a may be positioned at one end portion of buffer slot 301a in the width direction. The outlet 305a may be positioned on the side of the buffer slot 301a in the width direction. Additionally, the outlet 305a may be positioned at a corner where the side and top surfaces of the buffer slot 301a meet. Additionally, the outlet 305a may be positioned at a corner where the side and lower surfaces of the buffer slot 301a meet. Additionally, the outlet 305a may be positioned at the end portion of the upper surface of buffer slot 301a in the width direction. Additionally, the outlet 305a may be positioned at the end portion of the lower surface of the buffer slot 301 in the width direction a. FIG. 13 and FIG. 14 show an example where the outlet 305a is positioned on both sides of buffer slot 301a in the width direction. The plurality of outlets 305a may be provided along the length direction of the buffer slot 301a.

The outlet 305a may be connected to the exhaust 340a through the exhaust flow path 341a. The exhaust 340a may be connected to the outlet 305a to generate a negative pressure for the exhaust. The exhaust 340a may include a pump.

An outlet valve 346a may be disposed on the exhaust flow path 341a connecting the exhaust 340a and the outlet 305a. The exhaust state through the outlet 305a may be adjusted depending on the shutoff state of the outlet valve 346a. That is, when the outlet valve 346a is opened, the negative pressure is generated in the outlet 305a, and the exhaust is performed through the outlet 305a. When the outlet valve 346a is closed, the exhaust through outlet 305a is blocked.

The structure of exhaust flow path 341a is the same or similar to exhaust flow path 341 described above in FIG. 2 to FIG. 4, descriptions that would be repetitive may be omitted.

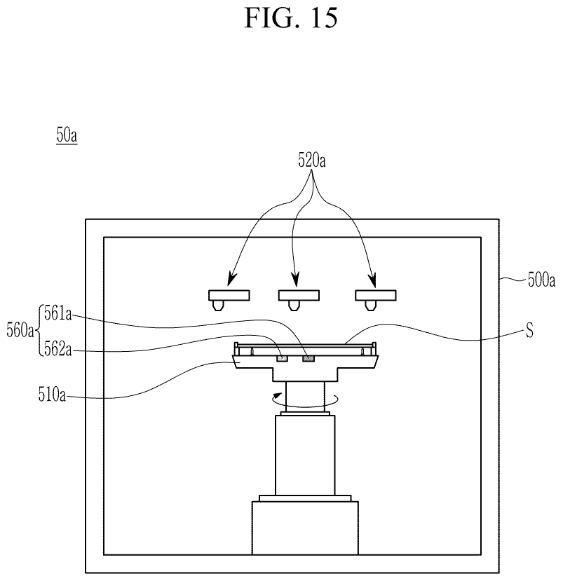

The buffer side sensor 320a may be disposed in the buffer frame 300a. The buffer side sensor 320a may detect the state of substrate S positioned in the buffer slot 301a. The buffer side sensor 320a may include a humidity sensor 321a and a temperature sensor 322a. The buffer side sensor 320a may be the same or similar to the buffer side sensor 320 described above in FIG. 2 to FIG. 4. In addition, the method by which the controller 70 controls the buffer chamber 30a may be the same or similar to the method described above in FIG. 9 to FIG. 12. Accordingly, repeated explanations are omitted. FIG. 15 is a cross-sectional view of a liquid treatment chamber 50a according to another embodiment.

Referring to FIG. 15, a liquid treatment chamber 50a may include a liquid treatment housing 500a, a support plate 510a, a fluid supply 520a, and a chamber side sensor 560a.

The chamber side sensor 560a may be disposed inside the liquid treatment housing 500a. The chamber side sensor 560a may detect the state of the substrate Sa positioned inside the liquid treatment housing 500a.

The chamber side sensor 560a may include a chamber side humidity sensor 561a and a chamber side temperature sensor 562a.

The chamber side humidity sensor 561a may be disposed on the support plate 510a. The chamber side humidity sensor 561a may be disposed on the upper surface of the support plate 510a. Accordingly, when the substrate S is positioned on the support plate 510a, the chamber side humidity sensor 561a may face the substrate S.

The chamber side humidity sensor 561a may detect the humidity of the substrate S. As an example, the chamber side humidity sensor 561a is provided as a non-contact humidity sensor and may directly sense the humidity of the substrate S positioned on the support plate 510a. In addition, the chamber side humidity sensor 561a is provided as a contact-type humidity sensor, and may detect the humidity of the space on the support plate 510a, and indirectly sense the humidity of the substrate S through this.

The chamber side temperature sensor 562a may be disposed on the support plate 510a. The chamber side temperature sensor 562a may be disposed on the upper surface of the support plate 510a. Accordingly, when the substrate S is positioned on the support plate 510a, the chamber side temperature sensor 562a may face the substrate S.

The chamber side temperature sensor 562a may detect the temperature of the substrate S. As an example, the chamber side temperature sensor 562a is provided as a non-contact temperature sensor and may detect the temperature of the substrate S positioned on the support plate 510a.

The remaining configuration of the liquid treatment chamber 50a is the same or similar to the liquid treatment chamber 50 described above in FIG. 7, descriptions that would be repetitive may be omitted. Additionally, the chamber side sensor 560a may be used interchangeably with the chamber side sensor 560 described above in FIG. 7. That is, the chamber side humidity sensor 561a and/or the chamber side temperature sensor 562a may be disposed in the fluid supply 520a like the liquid treatment chamber 50 described above in FIG. 7.

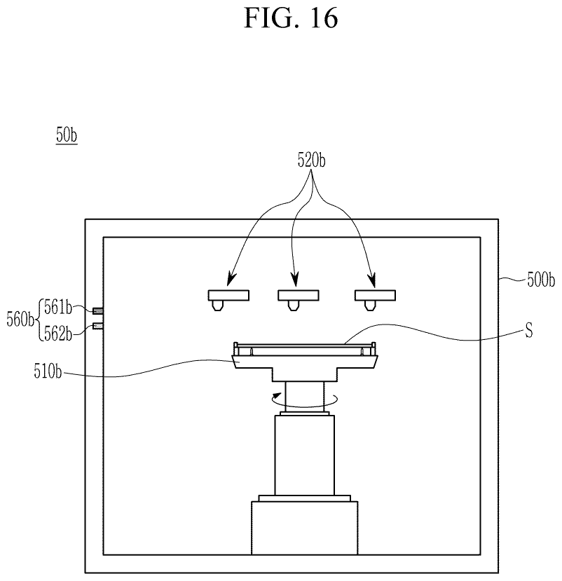

FIG. 16 is a cross-sectional view of a liquid treatment chamber 50b according to another embodiment.

Referring to FIG. 16, a liquid treatment chamber 50b may include a liquid treatment housing 500b, a support plate 510b, a fluid supply 520b, and a chamber side sensor 560b.

The chamber side sensor 560b may be disposed inside the liquid treatment housing 500b. The chamber side sensor 560b may detect a state of the substrate S positioned inside the liquid treatment housing 500b.

The chamber side sensor 560b may include a chamber side humidity sensor 561b and a chamber side temperature sensor 562b.

The chamber side humidity sensor 561b may be disposed on the inner surface of the liquid treatment housing 500b. As an example, the chamber side humidity sensor 561b may be disposed on the inner surface of the sidewall or the upper wall of the liquid treatment housing 500b. FIG. 16 shows a case where the chamber side humidity sensor 561b is disposed on the inner surface of the sidewall of the liquid treatment housing 500b.

The chamber side humidity sensor 561b may detect the humidity of the substrate S. As an example, the chamber side humidity sensor 561b is provided as a non-contact humidity sensor and may directly sense the humidity of the substrate S positioned on the support plate 510b. In addition, the chamber side humidity sensor 561b is provided as a contact-type humidity sensor, and may detect the humidity of the space on the support plate 510b, and indirectly sense the humidity of the substrate S through this.

The chamber side temperature sensor 562b may be disposed on the inner surface of the liquid treatment housing 500b. As an example, the chamber side temperature sensor 562b may be disposed on the inner surface of the sidewall or the upper wall of the liquid treatment housing 500b. In FIG. 16, a case where the chamber side temperature sensor 562b is disposed on the inner surface of the sidewall of the liquid treatment housing 500b is illustrated.

The chamber side temperature sensor 562b may detect the temperature of the substrate S. As an example, the chamber side temperature sensor 562b is provided as a non-contact temperature sensor and may detect the temperature of the substrate S positioned on the support plate 510b.

The remaining configuration of the liquid treatment chamber 50b is the same or similar to the liquid treatment chamber 50 described above in FIG. 7, descriptions that would be repetitive may be omitted. In addition, the chamber side sensor 560b may be used interchangeably with the chamber side sensor 560 described above in FIG. 7 or the chamber side sensor 560a described above in FIG. 15. That is, the chamber side humidity sensor 561b and/or the chamber side temperature sensor 562b may be disposed in the fluid supply 520b like the liquid treatment chamber 50 described above in FIG. 7. Additionally, the chamber side humidity sensor 561b and/or chamber side temperature sensor 562b may be disposed on the support plate 510b like the liquid treatment chamber 50a described above in FIG. 15.

While this disclosure has been described in connection with what is

presently considered to be practical exemplary embodiments, it is to be understood that the disclosure is not limited to the disclosed embodiments, but, on the contrary, is intended to cover various modifications and equivalent arrangements included within the spirit and scope of the appended claims.

### DESCRIPTION OF SYMBOLS

2: index module
3: process module
20: load port
22: index chamber
30: buffer chamber
40: transfer chamber
50: liquid treatment chamber
60: drying chamber
220: index robot
300: buffer frame
301: buffer slot
305: outlet
310: spray nozzle
320: buffer side sensor
321: humidity sensor
322: temperature sensor
400: transfer rail
401: transfer robot
410: robot side sensor
500: liquid treatment housing
510: support plate
520: fluid supply
560: chamber side sensor
561: chamber side humidity sensor
562: chamber side temperature sensor
600: drying housing
610: process fluid supply

What is claimed is:

1. A substrate processing apparatus comprising:
an index module including a load port configured to receive a substrate carrier; and
a process module connected to the index module, the process module including a transfer chamber, a process chamber, and a buffer chamber, and
wherein the process chamber is connected to the transfer chamber and the buffer chamber is disposed between the index module and the transfer chamber,
wherein the transfer chamber includes a transfer robot configured to transfer a substrate between the buffer chamber and the process chamber, and
wherein the buffer chamber includes
a buffer frame including a plurality of buffer slots, each buffer slot configured to store a respective substrate;
a spray nozzle disposed on the buffer frame and configured to spray a status improvement gas into a buffer slot of the plurality; and
at least one buffer side sensor disposed on the buffer frame and configured to detect a state of a substrate positioned in the buffer slot.

2. The substrate processing apparatus of claim 1, wherein:
the buffer frame includes an outlet extending into the buffer slot of the plurality.

3. The substrate processing apparatus of claim 1, wherein:
the spray nozzle is disposed at an end surface of the buffer slot in a width direction.

4. The substrate processing apparatus of claim 3, wherein:
the buffer frame includes an outlet positioned on at least one of an upper surface or a lower surface of the buffer slot.

5. The substrate processing apparatus of claim 1, wherein:
the spray nozzle is disposed on at least one of an upper surface or a lower surface of the buffer slot.

6. The substrate processing apparatus of claim 5, wherein:
the buffer frame includes an outlet positioned on an end surface of the buffer slot in a width direction.

7. The substrate processing apparatus of claim 1, wherein:
the at least one buffer side sensor includes
a humidity sensor configured to detect a humidity of a substrate positioned in the buffer slot; and
a temperature sensor configured to detect a temperature of the substrate positioned in the buffer slot.

8. The substrate processing apparatus of claim 1, wherein:
the transfer chamber further includes at least one robot side sensor disposed in the transfer robot and configured to detect a state of a substrate positioned in the transfer robot.

9. The substrate processing apparatus of claim 8, wherein:
the at least one robot side sensor includes
a robot side humidity sensor that detects a humidity of the substrate positioned in the transfer robot; and
a robot side temperature sensor that detects a temperature of the substrate positioned in the transfer robot.

10. The substrate processing apparatus of claim 8, wherein:
the transfer robot includes at least one arm, and
the at least one robot side sensor is disposed on an arm of the at least one arm.

11. The substrate processing apparatus of claim 1, wherein:
the process chamber includes
a liquid treatment chamber configured to perform a liquid treatment process to treat the substrate using a chemical; and
a drying chamber configured to dry the substrate using a supercritical fluid.

12. The substrate processing apparatus of claim 11, wherein:
the liquid treatment chamber includes
a liquid treatment housing;
a support plate disposed inside the liquid treatment housing and configured to support a substrate inside the liquid treatment housing;
a fluid supply configured to supply a fluid for substrate processing; and
at least one chamber side sensor configured to detect a state of the substrate inside the liquid treatment housing.

13. The substrate processing apparatus of claim 12, wherein:
the at least one chamber side sensor is disposed on the fluid supply.

14. The substrate processing apparatus of claim 12, wherein:
the at least one chamber side sensor is disposed on the support plate.

15. The substrate processing apparatus of claim 12, wherein:
the at least one chamber side sensor is disposed on an inner surface of the liquid treatment housing.

16. A substrate processing apparatus comprising:
an index module including a load port configured to receive a substrate carrier; and
a process module connected to the index module, the process module including a transfer chamber, a liquid treatment chamber, a drying chamber, and a buffer chamber, and
a controller,
wherein the liquid treatment chamber and the drying chamber are connected to the transfer chamber and the buffer chamber is disposed between the index module and the transfer chamber,
wherein the transfer chamber includes a transfer robot configured to transfer a substrate between the buffer chamber and the liquid treatment chamber and between the buffer chamber and the drying chamber, and
wherein the liquid treatment chamber is configured to treat the substrate using a chemical;
wherein the drying chamber is configured to dry the substrate using a fluid in a supercritical state; and
wherein the buffer chamber includes
a buffer frame including a plurality of buffer slots, each buffer slot of the plurality configured to store a respective a substrate,
a spray nozzle disposed on the buffer frame and configured to spray a status improvement gas toward in a buffer slot of the plurality, and
at least one buffer side sensor disposed on the buffer frame and configured to detect a state of the respective substrate stored in the buffer slot, and
wherein the controller is configured to cause the spray nozzle to spray the status improvement gas in response to a temperature of the respective substrate or a humidity of the respective substrate detected through the buffer side sensor passes a predetermined value.

17. The substrate processing apparatus of claim 16, wherein:
the transfer robot includes a carry-in arm configured to transfer a substrate from the buffer chamber to the liquid treatment chamber, and
the transfer chamber further includes a robot side sensor that is disposed on the transfer robot and is configured to detect a state of a substrate loaded in the carry-in arm.

18. The substrate processing apparatus of claim 17, wherein:
the controller is configured to cause the substrate loaded in the carry-in arm to be transferred to the buffer chamber in response to the temperature of the substrate loaded in the carry-in arm or the humidity of the substrate loaded in the carry-in arm detected through the robot side sensor passes a threshold value.

19. The substrate processing apparatus of claim 17, wherein:
the liquid treatment chamber includes
a liquid treatment housing;
a support plate disposed inside the liquid treatment housing and configured to support the substrate;
a fluid supply configured to supply a fluid for processing the substrate; and
at least one chamber side sensor configured to detect a state of a substrate positioned inside the liquid treatment housing,
wherein the controller is configured to cause the the substrate positioned in the liquid treatment chamber to be transferred to the buffer chamber in response to the temperature of the substrate positioned in the liquid treatment chamber or the humidity of the substrate positioned in the liquid treatment chamber detected through the chamber side sensor passes a threshold value.

20. A substrate processing apparatus comprising:
an index module including a load port configured to receive a substrate carrier;
a transfer chamber including a transfer robot configured to transfer a substrate to and from the load port;
a liquid treatment chamber connected to the transfer chamber and configured to treat the substrate using a chemical;
a drying chamber connected to the transfer chamber and configured to dry the substrate using a fluid in a supercritical state;
a buffer chamber disposed between the index module and the transfer chamber; and
a controller,
wherein the buffer chamber includes
a buffer frame including a plurality of buffer slots, each of the buffer slots configured to secure a respective substrate;
a spray nozzle disposed on the buffer frame and configured to spray a status improvement gas into a buffer slot of the plurality of buffer slots; and
at least one buffer side sensor disposed on the buffer frame and configured to detect a state of a substrate positioned in the buffer slot,
wherein
the transfer robot includes a carry-in arm configured to transfer a substrate from the buffer chamber to the liquid treatment chamber,
the transfer chamber further includes at least one robot side sensor that is disposed in the transfer robot and is configured to detect a state of a substrate loaded in the carry-in arm, and
the liquid treatment chamber includes
a liquid treatment housing;
a support plate disposed inside the liquid treatment housing and configured to support a substrate in the liquid treatment housing;
a fluid supply configured to supply a fluid for processing the substrate in the liquid treatment housing; and
at least one chamber side sensor configured to detect a state of the substrate positioned inside the liquid treatment housing.
